(19) United States
(12) Patent Application Publication
(10) Pub. No.: US 2025/0251440 A1
(43) Pub. Date: Aug. 7, 2025

(54) FAULT DETECTOR

(71) Applicant: DENSO CORPORATION, Kariya-city (JP)

(72) Inventor: KUNIHIKO MATSUDA, Kariya-city (JP)

(21) Appl. No.: 19/186,051

(22) Filed: Apr. 22, 2025

Related U.S. Application Data
(63) Continuation of application No. PCT/JP2023/037134, filed on Oct. 13, 2023.

(30) Foreign Application Priority Data
Oct. 25, 2022 (JP) 2022-170553

(51) Int. Cl. G01R 31/28; G01R 15/04; G01R 19/00

(52) U.S. Cl. CPC G01R 31/2839; G01R 15/04; G01R 19/0084

(57) ABSTRACT

A fault detector includes an inverter, an upper drive circuit, a lower drive circuit, pull-down resistors, and a determination unit. The inverter has upper and lower arm elements in each phase. The upper drive circuit configured to output a gate signal to the upper arm element. Pull-down resistors being two voltage-division resistors connected between an interarm connection node and a ground in each phase. The determination unit detects whether a fault occurs in at least the upper and lower arm elements, based on a voltage at a voltage-division node being a connection node between the voltage-division resistors. The power supply line is connected to the interarm connection node without a pull-resistor between the power supply line and the interarm connection node. The determination unit detects whether stuck-ON fault and a stuck-OFF faults occur in the upper and lower arm elements, based on the voltage at the voltage-division node.

### CROSS REFERENCE TO RELATED APPLICATIONS

The present application is a continuation application of International Patent Application No. PCT/JP2023/037134 filed on Oct. 13, 2023, which designated the U.S. and claims the benefit of priority from Japanese Patent Application No. 2022-170553 filed on Oct. 25, 2022. The entire disclosures of all of the above applications are incorporated herein by reference.

### TECHNICAL FIELD

The present disclosure relates to a fault detector.

### BACKGROUND

A device may be provided to detect faults in relays and other components such as semiconductor switching elements in an initial check of a circuit supplying power to a multiphase motor. For example, a fault detector may have pull-up and pull-down resistors connected to upper and lower arm connection nodes of respective phases of the inverter. The pull-down resistor for each phase may have two voltage-division resistors connected in series. A determination unit may be provided to determine stuck-ON faults (short circuit faults) and stuck-OFF faults (open circuit faults) of the motor relay based on the voltage at the voltage-division node, which is the connection node of the two voltage-division resistors.

### SUMMARY

The present disclosure describes a fault detector that includes an inverter, an arm element drive circuit, pull-down resistors, and a determination unit.

### BRIEF DESCRIPTION OF DRAWINGS

Objects, features and advantages of the present disclosure will become more apparent from the following detailed description made with reference to the accompanying drawings. In the drawings:

FIG. 1 is a circuit diagram of a fault detector according to an embodiment;

FIG. 2 is a diagram illustrating the configuration related to a voltage monitor for a U-phase in FIG. 1;

FIG. 3A is a diagram for determining an upper arm element stuck-ON fault without leak cut;

FIG. 3B is a diagram for determining an upper arm element stuck-ON fault with the upper arm element drive circuit stopped (with leak cut);

FIG. 4 is a diagram for determining an upper arm element stuck-OFF fault;

FIG. 5 is a diagram for determining a lower arm element stuck-ON fault;

FIG. 6 is a diagram for determining a lower arm element stuck-OFF fault;

FIG. 7 is a diagram of the normal current path during U-phase motor relay stuck-ON fault check;

FIG. 8 is a diagram of the abnormal current path during U-phase motor relay stuck-ON fault check;

FIG. 9 is a diagram for determining a U-phase motor relay stuck-ON fault;

FIG. 10 is a diagram of the normal current path during U-phase motor relay stuck-OFF fault check;

FIG. 11 is a diagram of the abnormal current path during U-phase motor relay stuck-OFF fault check; and

FIG. 12 is a diagram for determining a U-phase motor relay stuck-OFF fault.

### DETAILED DESCRIPTION

In a comparative example, at least the pull-down resistor of the voltage monitoring pull-up and pull-down resistors is provided inside the driver circuit IC, thereby suppressing an increase in the board mounting area. However, the basic concept is to detect faults using the voltage reduced by the pull-up resistor from the power supply line voltage. Therefore, whether the pull-up resistor is provided inside the driver circuit IC or mounted on the board, it remains necessary as a component. In particular, when the pull-up resistor is mounted on the board, there is potential to further reduce the board mounting area.

A fault detector according to the present disclosure includes an inverter, an upper drive circuit, a lower drive circuit, pull-down resistors, and a determination unit.

The inverter has an upper arm element and a lower arm element in each of phases of the inverter. The upper arm element and the lower arm element are formed in a bridge connection between a ground line and a power supply line connected to a battery. The inverter converts a DC power of the battery to supply a converted DC power to a phase winding of a multiphase motor. The upper drive circuit outputs a gate signal to the upper arm element. The lower drive circuit outputs a gate signal to the lower arm element.

Pull-down resistors are two voltage-division resistors connected between an interarm connection node and a ground in each of the phases. The pull-down resistors divide a voltage between the interarm connection node and the ground. The interarm connection node is a connection node between the upper arm element and the lower arm element in each of the phases. The determination unit detects whether a fault occurs in at least the upper arm element and the lower arm element, based on a voltage at a voltage-division node being a connection node between the two voltage-division resistors.

The power supply line is connected to the interarm connection node without a pull-up resistor between the power supply line and the interarm connection node.

The determination unit detects whether a stuck-ON fault and a stuck-OFF fault occur in the upper arm element and the lower arm element, based on the voltage at the voltage-division node in a situation where a leakage current flows to the ground from the upper drive circuit via the pull-down resistors at an operation of the upper drive circuit.

In the present disclosure, instead of using the voltage reduced by the pull-up resistor from the power supply line voltage as in the comparative example, a fault detection is performed by utilizing the voltage generated by the leak current from the upper arm element drive circuit flowing through the pull-down resistor. By eliminating the pull-up resistor for voltage monitoring, the number of components can be reduced, and the board mounting area required for the pull-up resistor can be further decreased.

In the comparative example, the leakage current from the (upper arm element) driving circuit to the pull-down resistor may cause the voltage float to increase, which may be an error factor. Thus, leakage current may be recognized as an undesirable effect in the comparative example. Then, stopping the operation of the drive circuit and cutting the leakage current when an error is detected in the motor relay may be regarded as a solution to reduce the error in the comparative example. In the present disclosure, by actively using the leakage current as the voltage source for voltage monitoring, the elimination of the pull-up resistor is made possible.

### Embodiment

The following describes a fault detector according to an embodiment with reference to the drawings. According to the present embodiment, the fault detector is adapted to a circuit that supplies power to a multiphase motor used, for example, as a steering assist motor in an electric power steering system. This fault detector detects stuck-ON faults (short circuit faults) and stuck-OFF faults (open circuit faults) of the upper and lower arm elements of the inverter and the motor relay during the initial check of the power supply circuit.

The ECU of the electric power steering system functions as the fault detector. The ECU includes, for example, a microcomputer, a pre-driver, and the like, and has a CPU (not shown), a ROM, a RAM, an 1/O, and a bus line connecting these components. The ECU executes software processing by executing a program stored in advance by the CPU, and control by hardware processing by a dedicated electronic circuit.

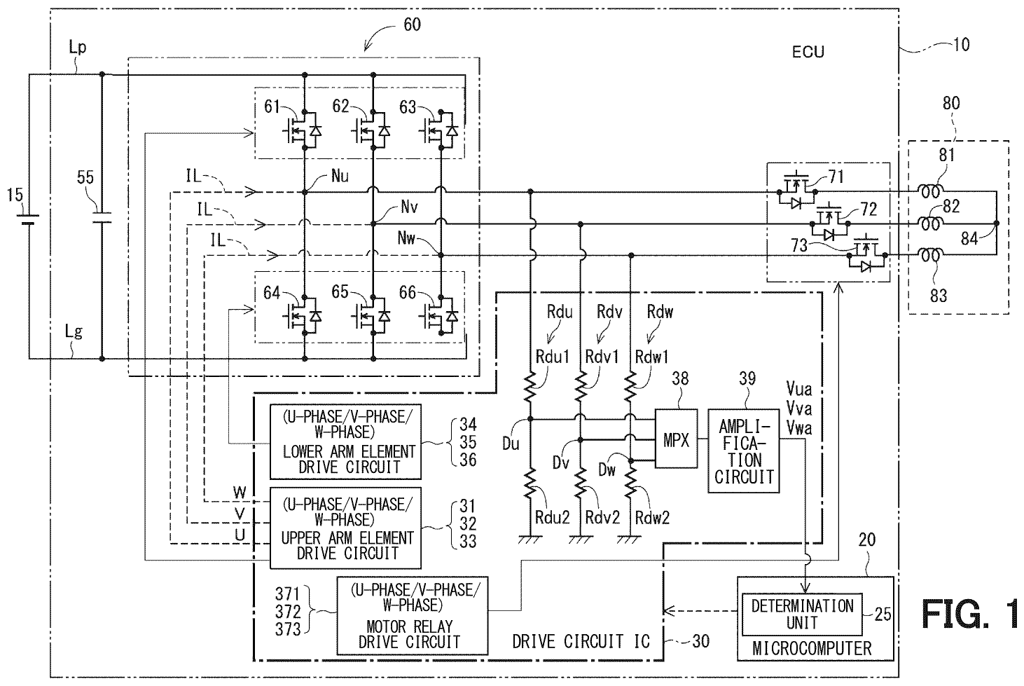

FIG. 1 illustrates the configuration according to the embodiment. A three-phase motor 80 is used as the “multiphase motor” in this system. The three-phase motor 80 is hereafter referred to simply as a motor 80. The ECU 10, functioning as the fault detector, supplies the three-phase AC power generated by the inverter 60 to the three-phase windings 81, 82, and 83 of the motor 80. For example, in the case of a Y-connected motor 80, the three-phase windings 81, 82, and 83 are connected at a neutral node 84. However, the three-phase windings 81, 82, and 83 may also be in delta connection.

The ECU 10 detects faults in the power supply circuit for supplying power to the motor as part of the initial check after the vehicle switch is turned ON and before the motor starts driving. If the power supply circuit to motor 80 is determined to be normal during the initial check, the ECU 10 controls the operation of motor 80 based on the steering torque to generate the desired assist torque.

The ECU 10 includes, for example, a smoothing capacitor 55, an inverter 60, motor relays 71, 72, 73, a drive circuit IC 30, and a microcontroller 20. The internal configuration of the drive circuit IC 30 is described hereinafter. The microcontroller 20 includes a determination unit 25 that detects a fault in a target element.

The inverter 60 is connected to the positive terminal of a battery 15 via a power supply line Lp and to the negative terminal of the battery 15 via a ground line Lg. The inverter 60 is provided with three phases, namely the U-phase, V-phase, and W-phase. Upper arm elements 61, 62, 63 and lower arm elements 64, 65, 66 are bridge-connected between the power supply line Lp and the ground line Lg. The upper arm elements 61, 62, 63 and lower arm elements 64, 65, 66 may hereinafter be collectively referred to as upper and lower arm elements 61-66. The inverter 60 converts a DC power of the battery 15 and then supplies the converted power to the three-phase windings 81, 82, 83 of the motor 80.

A smoothing capacitor 55 provided at the input unit of the inverter 60 smoothens the input voltage provided to the inverter 60. A power relay or a reverse connection protection relay may be provided in the power supply line Lp between the battery 15 and the inverter 60.

In the inverter 60, the connection nodes between the upper arm elements 61, 62, 63 and the lower arm elements 64, 65, 66 of each phase are defined as “arm connection nodes Nu, Nv, Nw.” Motor relays 71, 72, and 73 are provided in the motor current path that connects the connection nodes Nu, Nv, and Nw between the arms of each phase of the inverter 60 and the three-phase windings 81, 82, and 83 of the motor 80. The motor relays 71, 72, and 73 have parasitic diodes connected in parallel that conduct current from the inverter 60 side to the motor 80 side, and they block current from the motor 80 side to the inverter 60 side when turned off.

The upper and lower arm elements 61-66 and motor relays 71, 72, and 73 of this embodiment are MOSFETs. In the motor relays 71, 72, and 73, the parasitic diodes of the MOSFETs conduct current from the inverter 60 side to the motor 80 side. In the upper and lower arm elements 61-66, the parasitic diodes of the MOSFETs conduct current from the low potential side to the high potential side.

In a comparative example, pull-up resistors are provided to connect the power supply line Lp and the motor current path of each phase. In contrast, in this embodiment, the power supply line Lp and the inter-arm connection nodes Nu, Nv, and Nw of each phase are not connected via pull-up resistors. In other words, in the ECU 10 according to this embodiment, the pull-up resistor is removed compared to the comparative example.

The drive circuit IC 30 is a customized integrated IC. Inside the drive circuit IC 30, upper arm element drive circuits 31, 32, 33, lower arm element drive circuits 34, 35, 36, motor relay drive circuits 371, 372, 373, pull-down resistors Rdu, Rdv, Rdw for each phase, a multiplexer 38, and an amplification circuit 39 are provided.

The upper arm element drive circuits 31, 32, and 33 output gate signals to the upper arm elements 61, 62, and 63. The lower arm element drive circuits 34, 35, and 36 output gate signals to the lower arm elements 64, 65, and 66. The motor relay drive circuits 371, 372, and 373 output gate signals to the motor relays 71, 72, and 73. Each of the upper arm element drive circuits 31, 32, 33 may also be simply referred to as an upper arm drive circuit.

In the drawing, the block of “upper arm element drive circuits 31, 32, 33” is actually divided into three blocks: the U-phase upper arm element drive circuit 31, the V-phase upper arm element drive circuit 32, and the W-phase upper arm element drive circuit 33. However, due to space constraints, they are illustrated as a single block. The thin line arrows from the blocks of upper arm element drive circuits 31, 32, and 33 to the double-dotted frame surrounding upper arm elements 61, 62, and 63 collectively represent the gate signals to the upper arm elements 61, 62, and 63 in each phase.

The same applies to the lower arm element drive circuits 34, 35, and 36, as well as the motor relay drive circuits 371, 372, and 373. The block of lower arm element drive circuits 34, 35, and 36 collectively represents the U-phase lower arm element drive circuit 34, the V-phase lower arm element drive circuit 35, and the W-phase lower arm element drive circuit 36. The block of “motor relay drive circuits 371, 372, and 373” collectively represents the U-phase motor relay drive circuit 371, the V-phase motor relay drive circuit 372, and the W-phase motor relay drive circuit 373. Each of the lower arm element drive circuits 34, 35, and 36 may also be simply referred to as a lower drive circuit.

Additionally, the dashed lines connecting the block of “upper arm element drive circuits 31, 32, and 33” to the inter-phase connection nodes Nu, Nv, and Nw represent the path of the leakage current IL that flows during the operation of the upper arm element drive circuits 31, 32, and 33. The technical significance of the leakage current IL in this system is discussed below.

The pull-down resistors Rdu, Rdv, and Rdw are two voltage-division resistors per phase, which divide the voltage between the inter-arm connection nodes Nu, Nv, Nw of each phase and the ground, connecting the inter-arm connection nodes Nu, Nv, Nw to the ground. Among the two voltage-division resistors of each phase, the voltage-division resistor on the inter-arm connection node side, Nu, Nv, Nw, is referred to as the first voltage-division resistor Rdu1, Rdv1, Rdw1, and the voltage-division resistor on the ground side is referred to as the second voltage-division resistor Rdu2, Rdv2, Rdw2. Additionally, the connection nodes of the two voltage-division resistors are referred to as the voltage-division points Du, Dv, and Dw.

The voltages at the voltage-division nodes Du, Dv, and Dw of each phase are provided to a multiplexer (denoted as “MPX” in the figure) 38. The multiplexer 38 selects the voltage from one of the voltage-division nodes Du, Dv, or Dw of any phase and outputs the selected voltage to the amplification circuit 39. The amplification circuit 39 amplifies the voltage of the selected phase's voltage-division node Du, Dv, or Dw and outputs the amplified monitoring voltages Vua, Vva, Vwa to the determination unit 25.

The determination unit 25 directly detects faults in the upper and lower arm elements 61-66 of the inverter 60 and the motor relays 71, 72, and 73 based on the monitoring voltages Vua, Vva, and Vwa. Fundamentally, the determination unit 25 detects faults in the upper and lower arm elements 61-66 and the motor relays 71, 72, and 73 based on the voltages at the voltage-division nodes Du, Dv, and Dw when a leakage current IL flows to the ground via the pull-down resistors Pdu, Pdv, and Pdw from the upper arm element drive circuits 31, 32, and 33 during their operation. The dashed arrows from the microcontroller 20 to the drive circuit IC 30 collectively represent various signals.

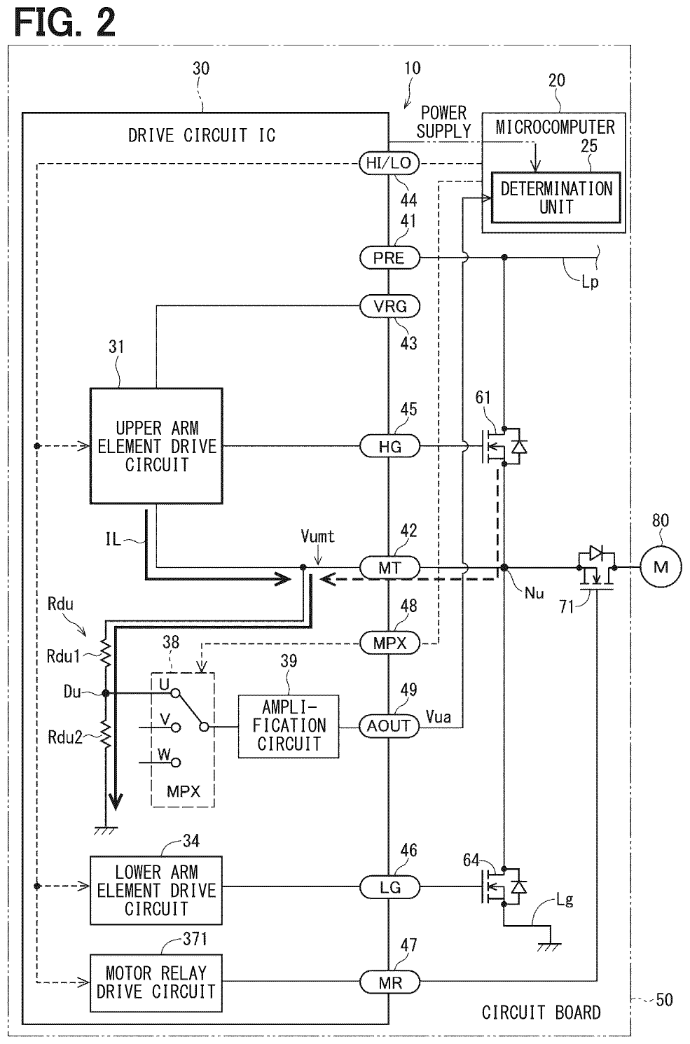

Next, referring to FIG. 2, the configuration related to voltage monitoring of a single phase, U-phase, will be explained. FIG. 2 illustrates that a pull-up resistor connected in parallel to the U-phase upper arm element 61 is not provided. In FIG. 2 of the present embodiment, the FETs in each of the drive circuits 31, 34, and 371 are omitted, and those including the FETs are described as drive circuits. The specific circuit diagram of the amplification circuit 39 is omitted, and only the block is indicated in FIG. 2.

Rdu1 and Rdu2 denote the voltage-division resistors. IL denotes the leakage current.

In FIG. 2, the U-phase is shown as a representative, and the reference numeral of the U-phase configuration element is used in the explanatory text. The same configuration applies to the V-phase and W-phase as well. On a circuit board 50, the microcontroller 20 and the drive circuit IC 30 are mounted as chips, and MOSFETs that include the upper arm element 61, the lower arm element 64, and the motor relay 71 are also mounted.

Inside the drive circuit IC 30, there are built-in circuits including the upper arm element drive circuit 31, the lower arm element drive circuit 34, and the motor relay drive circuit 371. Inside the drive circuit IC 30, there is a pull-down resistor Rdu in which two voltage-division resistors Rdu1 and Rdu2 connected in series, the multiplexer 38, and the amplification circuit 39. The multiplexer 38 is in a state where the voltage at the voltage-division node Du of the U-phase is provided.

During the operation of the upper arm element drive circuit 31, as indicated by the bold arrow, a leakage current IL flows from the upper arm element drive circuit 31 to ground via the pull-down resistor Rdu. During the ON operation of the upper arm element 61, a larger leakage current IL flows compared to when the upper arm element 61 is in the OFF operation. When the operation of the upper arm element drive circuit 31 stops, no leakage current IL flows. During the operation of the upper arm element drive circuit 31, when both the upper arm element 61 and the lower arm element 64 are OFF, the motor terminal voltage V·mt (where ·=u, v, w), which is the voltage at the arm connection nodes Nu, Nv, Nw of each phase, is expressed by equation (1). Here, R1 is the resistance value of the first voltage-division resistor Rd1, and R2 is the resistance value of the second voltage-division resistor Rd2.

$$V * mt = ( R 1 + R 2 ) \times IL \qquad ( 1 )$$

Further, the relationship between the monitor voltage Va input to the determination unit 25 and the motor terminal voltage V·mt (where ·=u, v, w) is expressed by equation (2), with G being the gain of the amplification circuit 39. In a circuit where the amplification circuit 39 is not provided, G=1 is considered. Thus, in this system, the voltage generated by the leakage current IL is used to detect faults.

$$V * a = G \times V \times mt \times R 2 / ( R 1 + R 2 ) = G \times R 2 \times IL \qquad ( 2 )$$

In the comparative example, the basic concept is to perform fault detection by utilizing the voltage that is stepped down by a pull-up resistor from the voltage of the power supply line Lp. Therefore, regardless of whether the pull-up resistor is provided inside the drive circuit IC 30 as in the comparative example, it is still required as a component. In particular, there is room to further reduce the board mounting area in the comparative example, where the pull-up resistor is mounted on the board.

In addition, by stopping the operation of the upper arm element drive circuit when an error is detected, the leakage current flowing through the pull-down resistor can be cut and the effect of the error can be minimized.

In the present embodiment, by adopting the reverse idea of actively utilizing the leakage current IL as a voltage source for voltage monitoring, it becomes possible to eliminate the pull-up resistor. In the present embodiment, by eliminating the pull-up resistor for voltage monitoring, it is possible to reduce the number of components and further reduce the board mounting area occupied by the pull-up resistor. Furthermore, by providing both the upper arm element drive circuit 31 and the pull-down resistor Rdu inside the same drive circuit IC 30, the terminal connections along the path of the leakage current IL are eliminated, resulting in a more stable voltage.

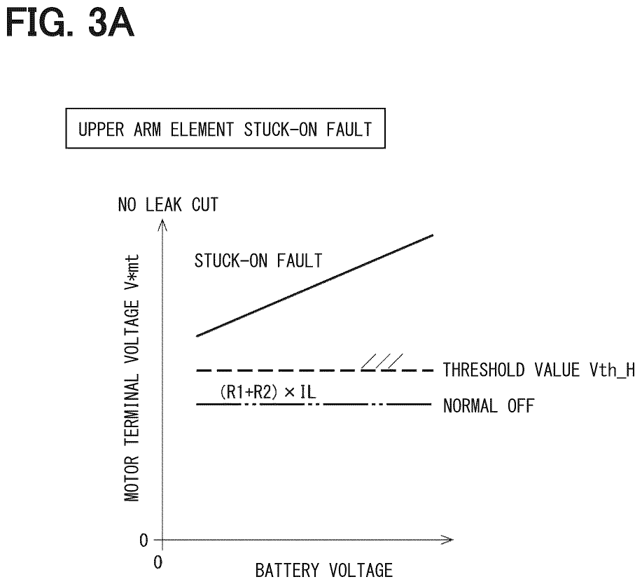

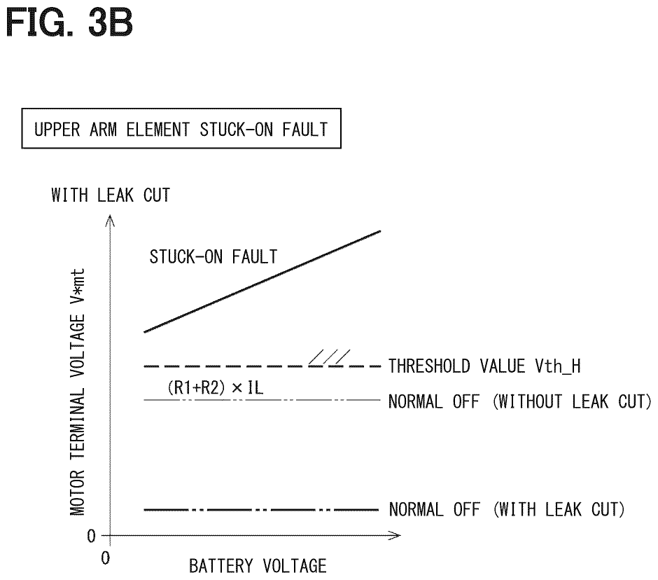

Next, a detailed explanation of the specific method for detecting faults in the upper and lower arm elements 61-66 and the motor relays 71, 72, and 73 according to this embodiment will be provided in order. First, with reference to FIGS. 3 to 6, an explanation will be provided on the detection of stuck-ON and stuck-OFF faults of the upper arm elements 61, 62, 63 and the lower arm elements 64, 65, 66. In the explanation, based on FIG. 2, the symbols for the U-phase upper arm element 61 and lower arm element 64, etc., will be used as representatives.

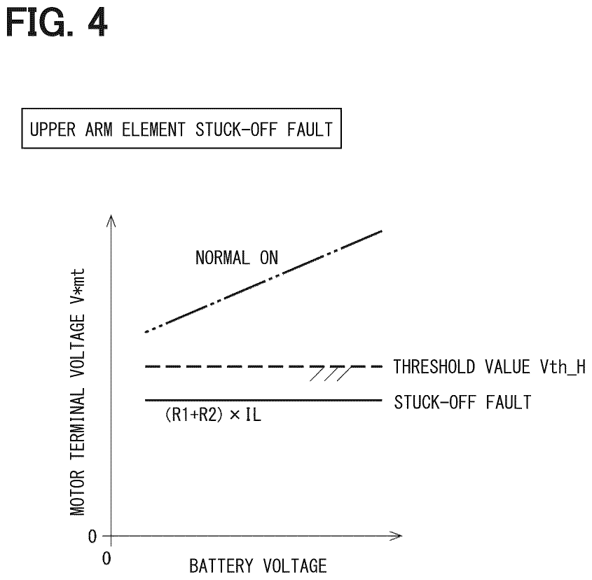

The determination unit 25 detects the stuck-ON fault and the stuck-OFF fault of the upper arm element 61 and the lower arm element 64 based on the voltage at the voltage dividing node Du when leakage current flows to the ground through the pull-down resistor Pdu from the upper arm element drive circuit 31 during the operation of the upper arm element drive circuit 31. In this disclosure, cutting the leakage current IL by stopping the operation of the upper arm element drive circuit 31 may be referred to as leakage cut. In this embodiment, leakage current IL is not cut off. FIGS. 4 to 6 show fault determination diagrams without leakage cut-off. Only the stuck-ON fault check for the upper arm element 61 is shown separately for the cases of “without leakage cut-off” and “with leakage cut-off” in FIGS. 3A and 3B.

The vertical axis of each figure indicates the values converted to motor terminal voltage V·mt (=u, v, w), rather than the monitor voltage V-a obtained by the determination unit 25. When both the upper arm element 61 and the lower arm element 64 are OFF, the value becomes “(R1+R2)×IL” as shown in equation (1).

Refer to FIGS. 3A, 3B, and 4 for the detection of stuck-ON and stuck-OFF faults of the upper arm element 61. The upper arm element 61 is operated to OFF during the check for stuck-ON fault and operated to ON during the check for stuck-OFF fault. The lower arm element 64 is turned off during any check.

As shown in FIG. 3A, during the stuck-ON fault check of the upper arm element 61, when it is normally OFF, the motor terminal voltage Vumt becomes “(R1+R2)×IL” and falls below the threshold value Vth_H. On the other hand, in the case of a stuck-ON fault of the lower arm element 64, the motor terminal voltage Vumt increases with the rise in battery voltage, exceeding the threshold value Vth_H.

In the stuck-ON fault check of the upper arm element 61, since the upper arm element 61 is turned OFF, it is also possible to stop the operation of the upper arm element drive circuit 31 to cut off leakage. Therefore, the determination unit 25 can detect the stuck-ON fault of the upper arm element 61 while the operation of the upper arm element drive circuit 31 is stopped. As shown in FIG. 3B, when leakage is cut off, the motor terminal voltage Vumt during normal OFF is near the ground level. As a result, a larger margin can be secured against false detection.

In the stuck-OFF fault check of the upper arm element 61, it is necessary to operate the upper arm element 61 to the ON state, so it is not possible to stop the operation of the upper arm element drive circuit 31 to cut the leakage current IL. As shown in FIG. 4, the motor terminal voltage Vumt during the normal ON state of the upper arm element 61 increases with the rise in battery voltage, within a range that exceeds the threshold value Vth_H. On the other hand, the motor terminal voltage Vumt during the stuck-OFF fault of the upper arm element 61 becomes “(R1+R2)×IL” and falls below the threshold value Vth_H.

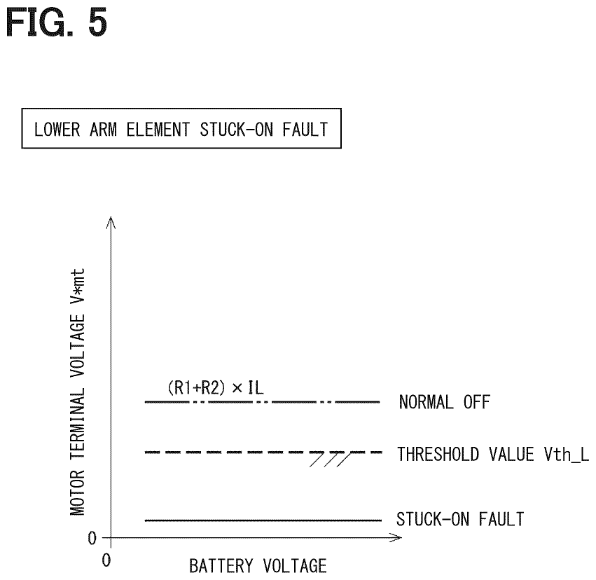

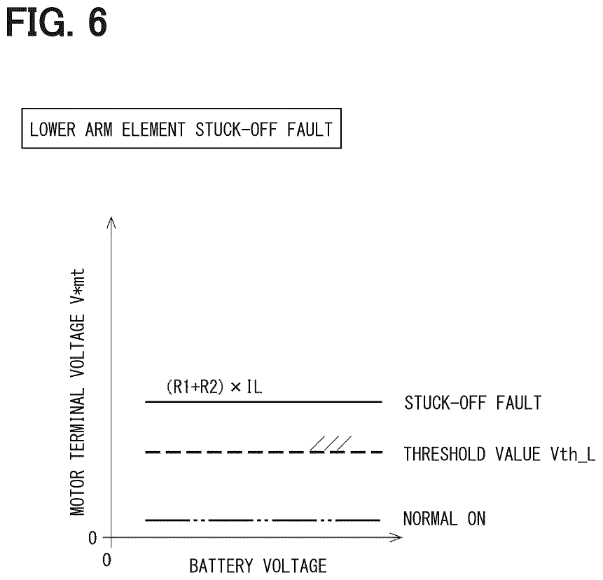

Next, regarding the detection of the stuck-ON fault and stuck-OFF fault of the lower arm element 64, refer to FIGS. 5 and 6. The lower arm element 64 is turned OFF during the check for stuck-ON fault and turned ON during the check for stuck-OFF fault. The upper arm element 61 is always turned off.

As shown in FIG. 5, during the stuck-ON fault check of the lower arm element 64, the motor terminal voltage Vumt in the normal OFF state becomes “(R1+R2)×IL” and exceeds the threshold value Vth_L. On the other hand, during the stuck-ON fault of the lower arm element 64, the motor terminal voltage Vumt is near the ground value and falls below the threshold value Vth_L. However, if a leakage cut is performed, the voltage in the normal OFF state decreases, making fault detection difficult. Therefore, it is not possible to perform a leakage cut during the stuck-ON fault check of the lower arm element 64.

As shown in FIG. 6, during the stuck-OFF fault check of the lower arm element 64, the motor terminal voltage Vumt when the lower arm element 64 is normally ON is near the ground value and falls below the threshold value Vth_L. On the other hand, during the stuck-OFF fault of the lower arm element 64, the motor terminal voltage Vumt becomes “(R1+R2)×IL” and exceeds the threshold value Vth_L.

As described above, by utilizing the leakage current flowing to the ground via the pull-down resistor from the upper arm element drive circuit of each phase for detecting the stuck-ON and stuck-OFF faults of the upper and lower arm elements 61-66 of the inverter 60, it is possible to eliminate the pull-up resistor for voltage monitoring. The determination unit 25 can ensure a greater margin against false detection by detecting the stuck-ON abnormalities of the upper arm elements 61, 62, and 63 while the operations of the upper arm element drive circuits 31, 32, and 33 are stopped.

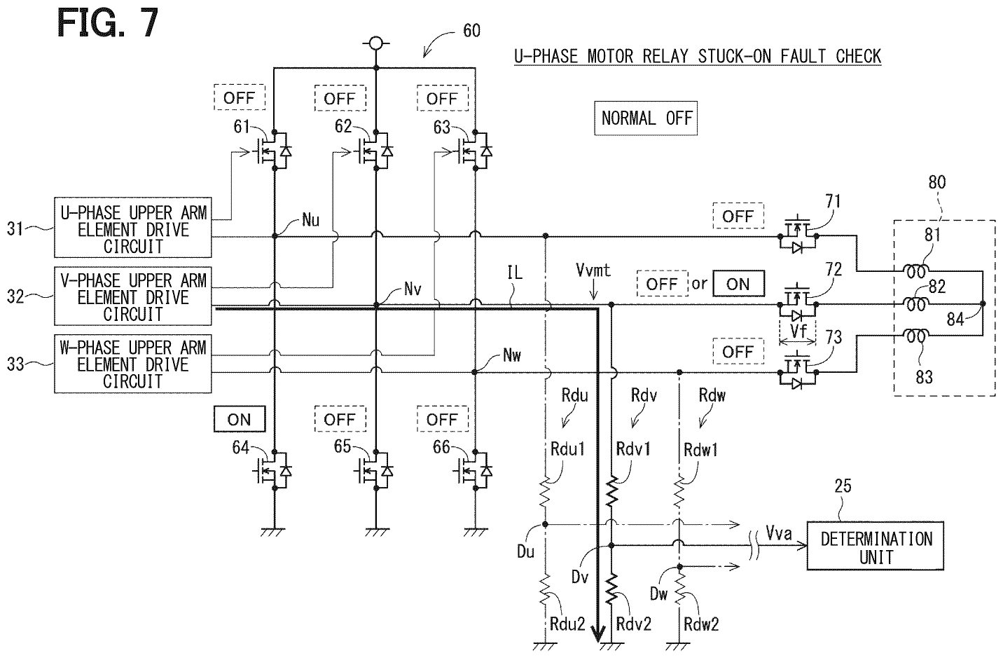

Next, with reference to FIGS. 7 to 12, the detection of stuck-ON and stuck-OFF abnormalities of the motor relays 71, 72, and 73 will be explained. The phase subject to fault detection is referred to as the target phase. Furthermore, among the two phases other than the target phase, the one or two phases whose voltage at the voltage-division node is used for fault detection by the determination unit 25 are referred to as the monitoring phase(s). Here, the case where the U-phase is the target phase and the V-phase is the monitoring phase will be explained as an example. When the U-phase is the target phase, the W-phase may be selected as the monitoring phase instead of or in addition to the V-phase. The multiplexer 38 and amplification circuit 39 are omitted in FIG. 7 and elsewhere.

The determination unit 25 performs fault detection by utilizing the voltage generated by the leak current from the upper arm element drive circuit of the monitoring phase flowing through the pull-down resistor. In fault detection of the motor relay, the operation of the upper arm element drive circuit of the monitoring phase is not stopped to cut off the leak current IL.

Refer to FIGS. 7 to 9 for the stuck-ON fault check of the U-phase motor relay 71. During the check for the stuck-ON fault, the motor relay 71 of the U-phase, which is the target phase, is operated to OFF. In addition, in the inverter 60, the upper arm elements 61, 62, and 63 of all phases, and the respective lower arm elements 65 and 66 of the V-phase and W-phase, which are the two phases other than the target phase, are turned OFF, and the lower arm element 64 of the U-phase, which is the target phase, is turned ON. In addition, the motor relay 73 for phase W, which is “a phase other than the target phase and other than the monitoring phase,” is turned off.

For the motor relay 72 of the monitoring V-phase, both OFF and ON states are possible. When the V-phase motor relay 72 is OFF, the current flowing from the inverter 60 side to the motor 80 side passes through the parasitic diode of the MOSFET, resulting in a voltage drop Vf across the parasitic diode. When the V-phase motor relay 72 is ON, the current flows through the main body of the MOSFET, resulting in a voltage drop that is close to zero.

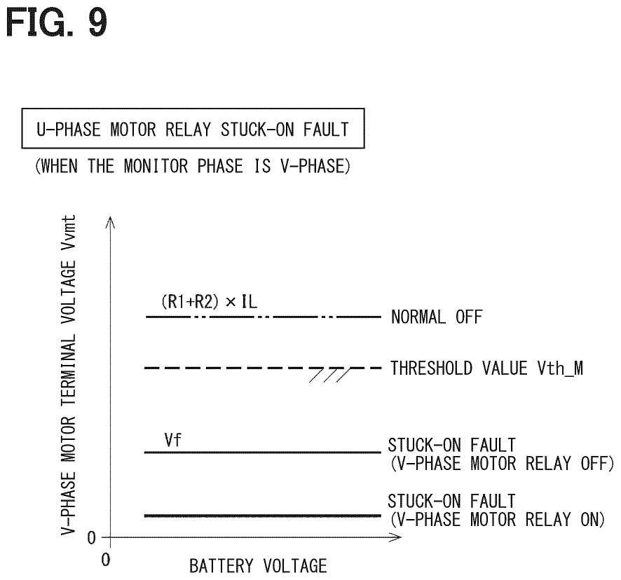

As shown in FIG. 7, when the U-phase motor relay 71 is normally OFF, the path for current flowing from the neutral node 84 of the motor 80 to the ground via the U-phase lower arm element 64 is interrupted by the U-phase motor relay 71. Consequently, the leakage current IL from the V-phase upper arm element drive circuit 32 flows entirely through the pull-down resistor Rdv. As shown in FIG. 9, the motor terminal voltage Vvmt when normally OFF is given by “(R1+R2)×IL”, which exceeds the threshold value Vth_M.

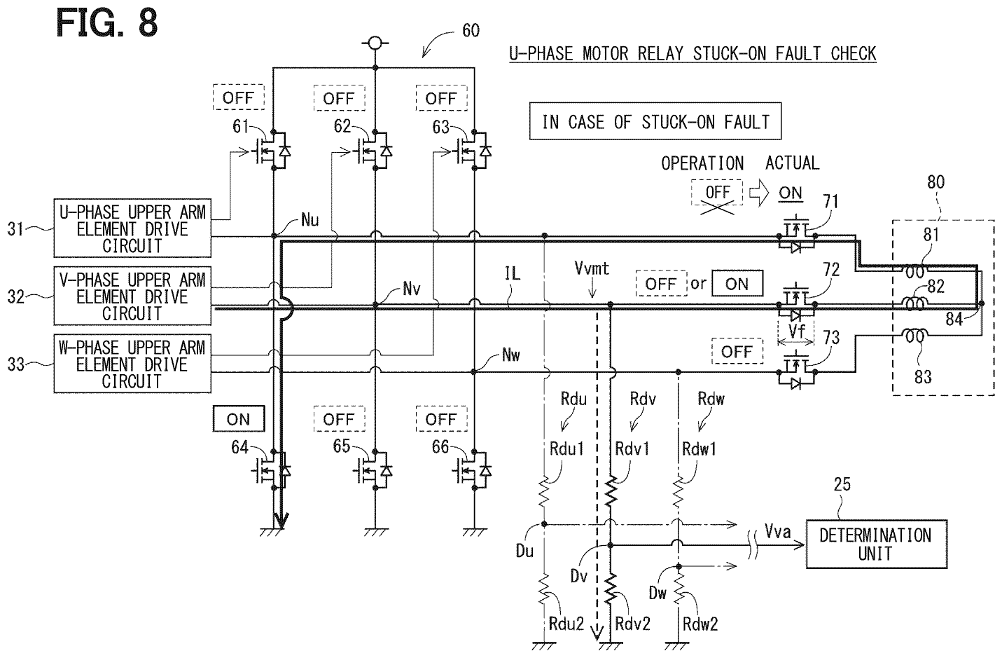

As shown in FIG. 8, when there is a stuck-ON fault in the U-phase motor relay 71, a conductive path is formed from the neutral node 84 of the motor 80 to the ground via the U-phase motor relay 71 and the U-phase lower arm element 64. Therefore, as indicated by the dashed line, only a small leakage current IL flows through the pull-down resistor Rdv.

As shown in FIG. 9, whether the V-phase motor relay 72 is ON or OFF, the motor terminal voltage Vvmt in the case of a stuck-ON fault remains below the threshold value Vth_M. When the V-phase motor relay 72 is OFF, the motor terminal voltage Vvmt in the case of a stuck-ON fault corresponds to the voltage drop Vf of the parasitic diode. In contrast, when the V-phase motor relay 72 is ON, the motor terminal voltage Vvmt in the case of a stuck-ON fault becomes a value near ground, allowing for a greater margin against false detection.

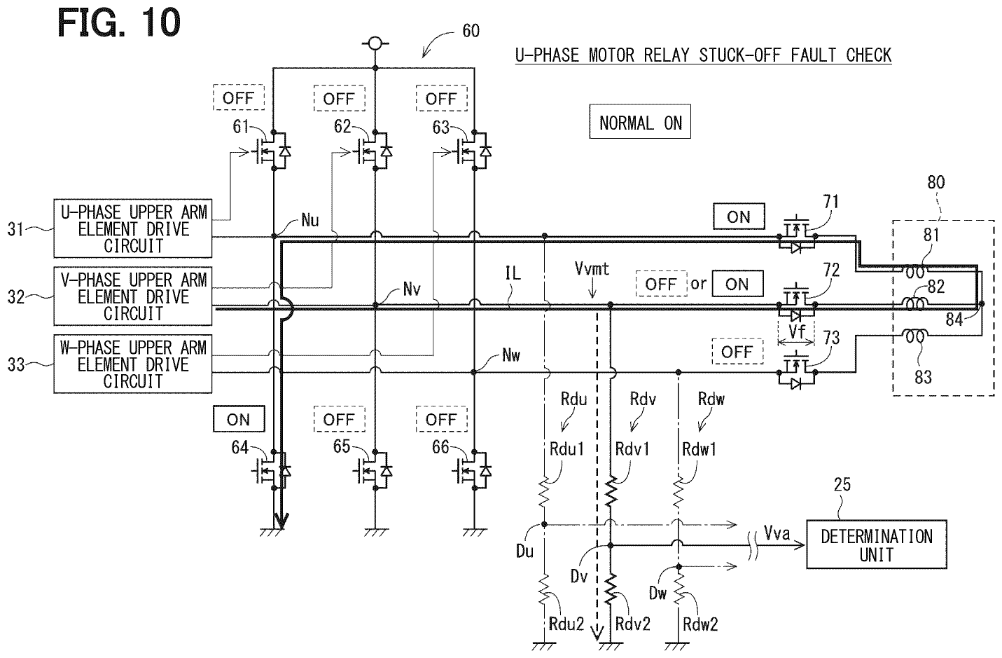

FIGS. 10 to 12 illustrate the stuck-OFF fault check of the U-phase motor relay 71. During the check for a stuck-OFF fault, the motor relay 71 of the target U-phase is operated to the ON position. Additionally, the ON/OFF states of the upper and lower arm elements 61-66 of the inverter 60, the motor relay 73 of the W-phase (which is not the monitoring phase), and the motor relay 72 of the V-phase (the monitoring phase) are handled in the same way as in the stuck-ON fault check.

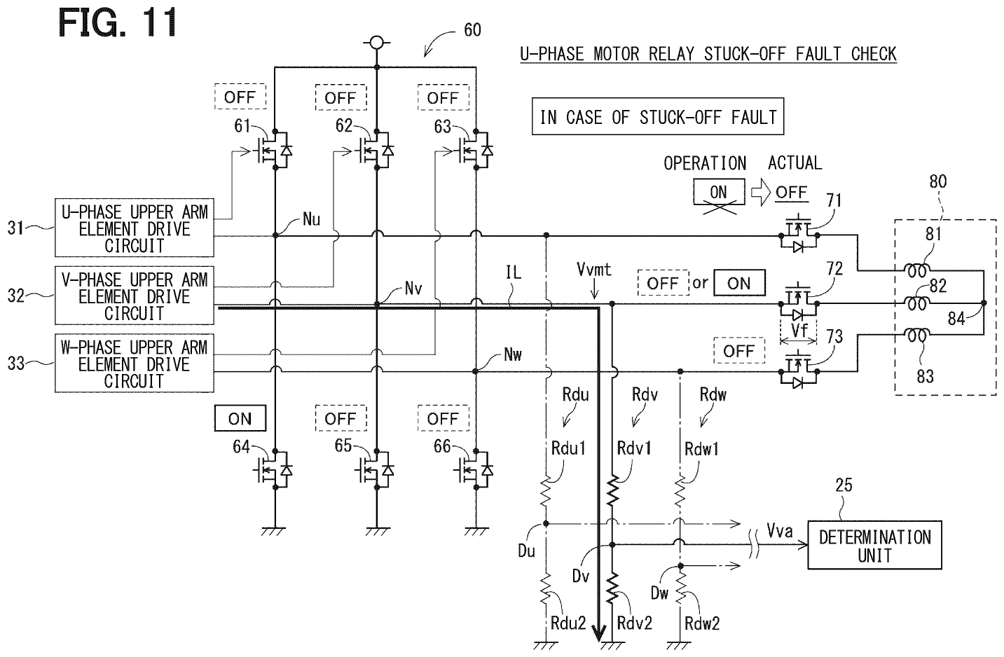

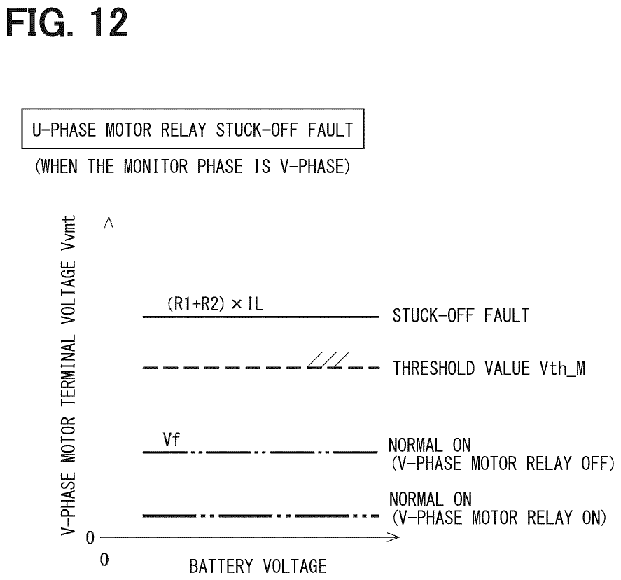

The current path during normal ON operation, as shown in FIG. 10, is the same as the current path during a stuck-ON fault, as illustrated in FIG. 8. The current path during a stuck-OFF fault, as shown in FIG. 11, is the same as the current path during normal OFF operation, as illustrated in FIG. 7. Therefore, as shown in FIG. 12, the motor terminal voltage Vvmt during a stuck-OFF fault is given by “(R1+R2)×IL” and exceeds the threshold value Vth_M.

Furthermore, as shown in FIG. 12, regardless of whether the V-phase motor relay 72 is ON or OFF, the motor terminal voltage Vvmt during normal ON operation remains below the threshold value Vth_M. When the V-phase motor relay 72 is OFF, the motor terminal voltage Vvmt during normal ON operation corresponds to the voltage drop Vf of the parasitic diode. On the other hand, when the V-phase motor relay 72 is ON, the motor terminal voltage Vvmt during normal ON operation is close to the ground level, thereby providing a larger margin against false detection.

As described above, by utilizing the leakage current IL that flows to the ground through the pull-down resistor from the upper arm element drive circuit of the monitoring phase, it is possible to detect both stuck-ON and stuck-OFF faults of the target phase motor relay. This allows for the elimination of the pull-up resistor used for voltage monitoring. The determination unit 25 detects stuck-ON and stuck-OFF faults of the U-phase motor relay 71, which is the target phase, based on the voltage at the voltage-division node Dv of the monitoring phase when the V-phase motor relay 72, which is the monitoring phase, is in the ON state and the leakage current IL is flowing. As a result, a larger margin can be secured against false detection.

### Other Embodiments

The fault detector described in the present disclosure may also be applied to power supply circuits that do not include motor relays. In that case, the determination unit 25 only needs to detect faults in at least the upper arm elements 61, 62, 63 and lower arm elements 64, 65, 66.

The pull-down resistors Pdu, Pdv, Pdw, the multiplexer 38, and the amplification circuit 39 are not limited to being provided inside the drive circuit IC 30; they may also be mounted on a circuit board. Additionally, the determination unit 25 is not limited to being inside the microcontroller 20; it may also be implemented as a logic circuit on a circuit board.

The multiplexer 38 does not need to be provided on the output side of each phase voltage-division node Du, Dv, Dw; instead, the amplification circuit 39 may be provided for each phase. In such cases, a multiplexer 38 may be provided on the output side of each phase's amplification circuit 39, allowing the monitor terminal to be shared.

The upper and lower arm elements 61-66 and the motor relays 71, 72, 73 are not limited to MOSFETs and may be composed of other semiconductor switching elements. For example, a flyback diode connected in parallel with a bipolar transistor is considered an equivalent element to the parasitic diode in a MOSFET.

The fault detector described in the present disclosure may have a dual-system configuration applied to a multiphase motor with two sets of multiphase windings. The multiphase motor is not limited to a three-phase motor and may also be a motor with four or more phases. Furthermore, the multiphase motor is not limited to the steering assist motor of an electric power steering system and may be used for other applications as well.

The present disclosure should not be limited to the embodiment described above. Various other embodiments may be implemented without departing from the scope of the present disclosure.

For example, according to an aspect of the present disclosure, the fault detector further includes motor relays and a motor relay drive circuit. Each of the motor relays is located at a motor current path connected between the interarm connection node and the phase winding and is connected to a parasitic diode in parallel in a corresponding one of the phases of the inverter. The parasitic diode conducts a current flowing from the inverter to the multiphase motor. The motor relays block a current flowing from the multiphase motor to the inverter at off state of the motor relays. The motor relay drive circuit outputs a gate signal to the motor relays. The determination unit is configured to detect whether the stuck-ON fault and the stuck-OFF fault occur in a motor relay in a target phase among the phases of the multiphase motor, based on the voltage at the voltage-division node during a flow of the leakage current. Additionally, according to another aspect of the present disclosure, in the fault detector, the determination unit detects whether the stuck-ON fault occurs in the upper arm element in a situation where the operation of the upper drive circuit is stopped. Both of the above aspects may also be combined together.

The fault detector and the technique according to the present disclosure may be achieved by a dedicated computer provided by constituting a processor and a memory programmed to execute one or more functions embodied by a computer program. Alternatively, the fault detector and the technique according to the present disclosure may be achieved by a dedicated computer provided by constituting a processor with one or more dedicated hardware logic circuits. Alternatively, the fault detector and the technique according to the present disclosure may be achieved using one or more dedicated computers constituted by a combination of the processor and the memory programmed to execute one or more functions and the processor with one or more hardware logic circuits. The computer program may be stored in a computer-readable non-transitory tangible recording medium as an instruction executed by the computer.

The present disclosure has been made in accordance with the embodiments. However, the present disclosure is not limited to such embodiments and configurations. The present disclosure also encompasses various modifications and variations within the scope of equivalents. Furthermore, various combination and formation, and other combination and formation including one, more than one or less than one element may be made in the present disclosure.

What is claimed is:

1. A fault detector comprising:
an inverter having an upper arm element and a lower arm element in each of phases of the inverter, the upper arm element and the lower arm element formed in a bridge connection between a ground line and a power supply line connected to a battery, the inverter configured to convert a DC power of the battery to supply a converted power to a phase winding of a multiphase motor, the phase winding adapted to each of the phases;
an upper drive circuit configured to output a gate signal to the upper arm element;
a lower drive circuit configured to output a gate signal to the lower arm element;
pull-down resistors being two voltage-division resistors connected between an interarm connection node and a ground in each of the phases, the pull-down resistors configured to divide a voltage between the interarm connection node and the ground, the interarm connection node being a connection node between the upper arm element and the lower arm element in each of the phases; and
a determination unit configured to detect whether a fault occurs in at least the upper arm element and the lower arm element, based on a voltage at a voltage-division node being a connection node between the two voltage-division resistors, wherein
the power supply line is connected to the interarm connection node in each of the phases without a pull-up resistor between the power supply line and the interarm connection node, and
the determination unit is configured to detect whether a stuck-ON fault and a stuck-OFF fault occur in the upper arm element and the lower arm element, based on the voltage at the voltage-division node in a situation where a leakage current flows to the ground from the upper drive circuit via the pull-down resistors during an operation of the upper drive circuit.

2. The fault detector according to claim 1, wherein
the determination unit is configured to detect whether the stuck-ON fault occurs in the upper arm element in a situation where the operation of the upper drive circuit is stopped.

3. The fault detector according to claim 1, further comprising:
motor relays, each of which is located at a motor current path connected between the phase winding and the interarm connection node in a corresponding one of the phases of the inverter and is connected to a parasitic diode in parallel, the parasitic diode configured to conduct a current flowing from the inverter to the multiphase motor, the motor relays configured to block a current flowing from the multiphase motor to the inverter at off state of the motor relays; and
a motor relay drive circuit configured to output a gate signal to the motor relays, wherein
the determination unit is configured to detect whether the stuck-ON fault and the stuck-OFF fault occur in a motor relay in a target phase among the phases, based on the voltage at the voltage-division node during a flow of the leakage current.

4. The fault detector according to claim 3, wherein
the multiphase motor is a three-phase motor,
at least one of the phases is a monitoring phase other than the target phase, the monitoring phase being a phase in which the voltage at the voltage-division node is used for a fault detection executed by the determination unit,
the determination unit is configured to detect whether the stuck-ON fault and the stuck-OFF fault occur in the motor relay in the target phase, based on the voltage at the voltage-division node in the monitoring phase during a flow of the leakage current, in a situation where:
the upper arm element in each of the phases is turned off;
the lower arm element in each of two of the phases other than the target phase is turned off;
the lower arm element in the target phase is turned on; and
at least a motor relay in a phase other than the target phase and other than the monitoring phase is turned off.

5. The fault detector according to claim 4, wherein
the determination unit is configured to detect whether the stuck-ON fault and the stuck-OFF fault occur in the motor relay in the target phase, based on the voltage at the voltage-division node in the monitoring phase during a flow of the leakage current, in a situation where a motor relay in the monitoring phase is turned on.

6. The fault detector according to claim 1, wherein
the pull-down resistors are located inside a drive circuit IC in which the upper drive circuit is embedded.

7. A fault detector comprising:
an inverter having an upper arm element and a lower arm element in each of phases of the inverter, the upper arm element and the lower arm element formed in a bridge connection between a ground line and a power supply line connected to a battery, the inverter configured to convert a DC power of the battery to supply a converted power to a phase winding of a multiphase motor, the phase winding adapted to each of the phases;
an upper drive circuit configured to output a gate signal to the upper arm element;
a lower drive circuit configured to output a gate signal to the lower arm element;
pull-down resistors being two voltage-division resistors connected between an interarm connection node and a ground in each of the phases, the pull-down resistors configured to divide a voltage between the interarm connection node and the ground, the interarm connection node being a connection node between the upper arm element and the lower arm element in each of the phases; and
a processor and a memory that stores instructions configured to, when executed by the processor, cause the processor to:
detect whether a fault occurs in at least the upper arm element and the lower arm element, based on a voltage at a voltage-division node being a connection node between the two voltage-division resistors; and
detect whether a stuck-ON fault and a stuck-OFF fault occur in the upper arm element and the lower arm element, based on the voltage at the voltage-division node in a situation where a leakage current flows to the ground from the upper drive circuit via the pull-down resistors during an operation of the upper drive circuit, wherein
the power supply line is connected to the interarm connection node in each of the phases without a pull-up resistor between the power supply line and the interarm connection node.
